(19) United States
(12) Patent Application Publication
(10) Pub. No.: US 2020/0066878 A1
(43) Pub. Date: Feb. 27, 2020

(54) METAL OXIDE SEMICONDUCTOR DEVICE CAPABLE OF REDUCING ON-RESISTANCE AND MANUFACTURING METHOD THEREOF

(71) Applicant: RICHTEK TECHNOLOGY CORPORATION, Zhubei City (TW)

(72) Inventor: Tsung-Yi Huang, Hsinchu (TW)

(21) Appl. No.: 16/447,820

(22) Filed: Jun. 20, 2019

(30) Foreign Application Priority Data
Aug. 23, 2018 (TW) 107129519

(51) Int. Cl. H01L 29/66; H01L 29/78; H01L 21/266; H01L 21/8234

(52) U.S. Cl. CPC H01L 29/66492; H01L 21/823425; H01L 21/266; H01L 29/7836

(57) ABSTRACT

A MOS device has a reduced ON-resistance; the MOS device has a first lightly doped diffusion (LDD) region which is longer than a second LDD region thereof, and the impurity concentration of the second LDD region is higher than that of the first LDD region. Another MOS device has a spacer layer on a drain sidewall of the gate but does not have a spacer layer on a source sidewall of the gate, wherein the drain sidewall is a sidewall of the gate conductive layer that is adjacent to the drain, and the source sidewall is a sidewall of the gate conductive layer that is adjacent to the source. The MOS device has a higher breakdown voltage, lower ON-resistance, and mitigates the threshold voltage roll-off and other short channel effects.

### CROSS REFERENCE

The present invention claims priority to TW 107129519, filed on Aug. 23, 2018.

### BACKGROUND OF THE INVENTION

### Field of Invention

The present invention relates to a metal oxide semiconductor (MOS) device and a manufacturing method thereof; particularly, it relates to such MOS device which has a reduced ON-resistance and an increased breakdown voltage, and a manufacturing method thereof.

### Description of Related Art

FIG. 1A is a schematic diagram of a cross-section view showing steps for forming lightly doped diffusion (LDD) regions 16a and 16b in a prior art metal oxide semiconductor (MOS) device 10. As shown in FIG. 1A, the MOS device 10 is formed in a semiconductor layer 11, wherein a semiconductor layer 12, a well 13, an isolation structure 14, a gate 15, and the LDD regions 16a and 16b are first formed. The isolation structure 14 defines a device region 14a which is a major operation region of the MOS device 100. The gate 15 is formed by steps including: first forming a dielectric layer 151 and a conductive layer 152; next forming the LDD regions 16a and 16b; and further next forming a spacer layer 153 after the LDD regions 16a and 16b are formed (referring to FIG. 1B). The LDD regions 16a and 16b are formed by steps including: using the dielectric layer 151 and the conductive layer 152 as a mask; and implanting N-type impurities in the device region 14a in the form of accelerated ions with an angle α with reference to a vertical direction (as indicated by a solid arrow shown in FIG. 1A). As shown in FIG. 1A, the LDD region 16a is located below one side of the spacer layer 153 and below part of the dielectric layer 151 near a source side of the gate 15, wherein the source side of the gate 15 is a side that is closer to a source 17 (referring to FIG. 1B), and the LDD region 16a is located between the source 17 and the well 13 and is adjacent to the source 17. The LDD region 16b is located below another side of the spacer 153 and below part of the dielectric layer 151 near a drain side of the gate 15, wherein the drain side of the gate 15 is a side that is closer to a drain 18 (referring to FIG. 1B), and the LDD region 16a is located between the drain 18 and the well 13 and is adjacent to the drain 18. FIG. 1B is a schematic diagram of a cross-section view showing steps for forming the source 17 and the drain 18 in the MOS device 100. As shown in FIG. 1B, the source 17 and the drain 18 are formed by steps including: using the spacer layer 153 and the conductive layer 152 as a mask; and implanting N-type impurities in the device region 14a in the form of accelerated ions.

As is well known, when the MOS device 10 is OFF, an OFF-resistance between the source 17 and the drain 18 is extremely high, and as thus there is zero current flowing between the source 17 and the drain 18. When the gate-source voltage (Vgs) exceeds a threshold voltage (Vth), the MOS device 100 is turned ON, and the drain 18 and the source 17 are electrically connected with each other via a channel which has an ON-resistance equal to Rds(on).

The LDD regions 16a and 16b are regions extended from the source 17 and drain 18 toward the channel, wherein the LDD regions 16a and 16b have lower N-type impurity concentrations than the N-type source 17 and drain 18. AMOS device which has LDD regions such as the MOS device 10, forms an electrical field which is closer to the drain and the field intensity thereof is lower, as compared to a MOS device which has no LDD regions. As thus, hot carrier effect of the MOS device which has LDD regions is mitigated. Besides, during operation of the MOS device, some electrons might move toward the gate 15 and penetrate through the interface between the dielectric layer 151 and the channel to be trapped in the dielectric layer 151; the LDD regions 16a and 16b also mitigate such a problem.

In order to reduce the ON-resistance between the source 17 and the drain 18, it is preferred that the impurity concentrations of the LDD regions 16a and 16b should be increased (but still lower than the source 17 and the drain 18); however, this will decrease breakdown voltage of the MOS device 10, which is a dilemma.

In view of above, to improve the prior art, the present invention proposes a MOS device having a reduced ON-resistance, and a manufacturing method thereof.

### SUMMARY OF THE INVENTION

In one perspective, the present invention provides a metal oxide semiconductor (MOS) device, comprising: a semiconductor layer which has a top surface and a bottom surface opposite to the top surface in a vertical direction; a well having a first conductivity type, which is formed in the semiconductor layer, wherein the well is located below and in contact with the top surface; a gate, which is formed on the top surface, wherein part of the well is located below and in contact with the gate in the vertical direction, the gate including: a dielectric layer, which is formed on and in contact with the top surface, and is in contact with the well in the vertical direction; a conductive layer, which is formed on and in contact with the dielectric layer, and serves as an electrical contact of the gate; and a spacer layer, which is formed on two sidewalls of the conductive layer, and serves as an electrical insulation layer of the gate; a source and a drain which have a second conductivity type and are formed below and in contact with the top surface in the vertical direction, wherein the source and the drain are located below and outside two sides of the gate respectively, and wherein the source and the drain are located in the well; a first lightly doped diffusion (LDD) region having the second conductivity type, which is formed below the dielectric layer and the spacer layer, wherein the first LDD region is in contact with the drain; and a first part of a second lightly doped diffusion (LDD) region having the second conductivity type, which is formed below and in contact with the spacer layer, wherein the first part of the second LDD region is in contact with the source; wherein a length of the first LDD region is longer than a length of the first part of the second LDD region; and wherein an impurity concentration of the first part of the second LDD region is higher than an impurity concentration of the first LDD region.

In one preferable embodiment, the first conductivity type is a P-type semiconductor conductivity type and the second conductivity type is an N-type semiconductor conductivity type; or the first conductivity type is an N-type semiconductor conductivity type and the second conductivity type is a P-type semiconductor conductivity type.

In one preferable embodiment, the first LDD region is formed by a first self-alignment process, and the first self-alignment process includes: using the conductive layer and the dielectric layer as a mask; and implanting second conductivity type impurities in the semiconductor layer in the form of accelerated ions with a first angle with reference to the vertical direction.

In one preferable embodiment, the first part of the second LDD region is formed by a second self-alignment process, and the second self-alignment process includes: using the conductive layer as a mask; and implanting second conductivity type impurities in the semiconductor layer through the spacer layer in the form of accelerated ions with a second angle with reference to the vertical direction, wherein the first angle is larger than the second angle.

In one preferable embodiment, the MOS device further includes a second part of the second LDD region, wherein the second part of the second LDD region is located in the first LDD region, and the second part of the second LDD region is formed below and in contact with the spacer layer.

In one preferable embodiment, a depth of the first LDD region is deeper than a depth of the second LDD region.

From another perspective, the present invention provides a metal oxide semiconductor (MOS) device, including: a semiconductor layer which has a top surface and a bottom surface opposite to the top surface in a vertical direction; a well which has a first conductivity type and is formed in the semiconductor layer, wherein the well is located below and in contact with the top surface; a gate, which is formed on the top surface, wherein part of the well is located below and in contact with the gate in the vertical direction, the gate including: a dielectric layer, which is formed on and in contact with the top surface, and is in contact with the well in the vertical direction; a conductive layer, which is formed on and in contact with the dielectric layer, and serves as an electrical contact of the gate; and a spacer layer, which is formed on and in contact with a drain sidewall of the conductive layer but is not formed on and in contact with a source sidewall of the conductive layer, to serve as an electrical insulation layer of the gate, wherein the drain sidewall is a sidewall of the conductive layer that is adjacent to the drain, and the source sidewall is a sidewall of the conductive layer that is adjacent to the source; a source and a drain which have a second conductivity type and are formed below and in contact with the top surface in the vertical direction; wherein the source is located below and outside the source sidewall of the conductive layer; wherein the drain is located below and outside the spacer layer of the gate; and a first lightly doped diffusion (LDD) region having the second conductivity type, which is formed below the dielectric layer and the spacer layer, wherein the first LDD region is in contact with the drain.

From another perspective, the present invention provides a manufacturing method of a metal oxide semiconductor (MOS) device, the manufacturing method comprising: providing a semiconductor layer, which has a top surface and a bottom surface opposite to the top surface in a vertical direction; forming a well having a first conductivity type in the semiconductor layer, wherein the well is located below and in contact with the top surface; forming a dielectric layer of a gate on the top surface, and forming a conductive layer on the dielectric layer; defining a first region below a drain sidewall of the conductive layer; forming a first lightly doped diffusion (LDD) region in the first region by a first self-alignment process, wherein the first LDD region has a second conductivity type and is below and in contact with the dielectric layer; defining a second region below a source sidewall of the conductive layer, wherein the first region and the second region are separated by the well; forming a first part of a second LDD region in the second region by a second self-alignment process, wherein the second LDD region has the second conductivity type; forming a first spacer layer and a second spacer layer outside and in contact with the drain sidewall and the source sidewall of the conductive layer respectively, wherein the first LDD region is below and in contact with the first spacer layer and part of the dielectric layer, and the first part of the second LDD region is below and in contact with the second spacer layer; and forming a drain and a source having the second conductivity type in the first region and the second region respectively, wherein the first LDD region is in contact with the drain and the first part of the second LDD region is in contact with the source; wherein the drain sidewall is a sidewall of the conductive layer that is adjacent to the drain, and the source sidewall is a sidewall of the conductive layer that is adjacent to the source; wherein a length of the first LDD region is longer than a length of the first part of the second LDD region; and wherein an impurity concentration of the first part of the second LDD region is higher than an impurity concentration of the first LDD region.

From another perspective, the present invention provides a manufacturing method of a metal oxide semiconductor (MOS) structure, wherein the MOS structure includes two MOS devices which are arranged in mirror arrangement; wherein the two MOS devices share one common source.

The objectives, technical details, features, and effects of the present invention will be better understood with regard to the detailed description of the embodiments below.

### BRIEF DESCRIPTION OF THE DRAWINGS

FIG. 1A is a schematic diagram of a cross-section view showing steps for forming lightly doped diffusion (LDD) regions 16a and 16b in a prior art metal oxide semiconductor (MOS) device 10.

FIG. 1B is a schematic diagram of a cross-section view showing steps for forming source 17 and drain 18 in the prior art MOS device 10.

FIG. 2 is a schematic diagram of a cross-section view showing a MOS device capable of reducing ON-resistance according to the present invention (a first embodiment).

FIG. 3 is a schematic diagram showing steps for forming a first LDD region 24 and a second LDD region 26.

FIG. 4 shows a second embodiment of the present invention.

FIG. 5 shows a third embodiment of the present invention.

FIGS. 6A and 6B are schematic diagrams showing steps for forming the first LDD region 24.

FIGS. 7A-7J are schematic diagrams showing a manufacturing method of a MOS device 20 according to the present invention.

FIGS. 8A-8I are schematic diagrams showing a manufacturing method of another MOS device 20 according to the present invention.

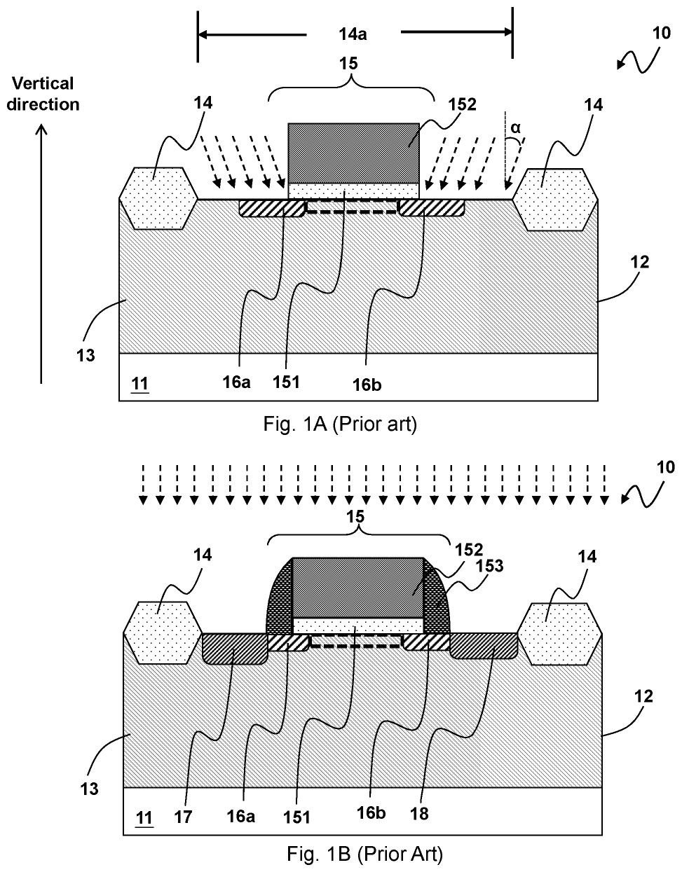

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

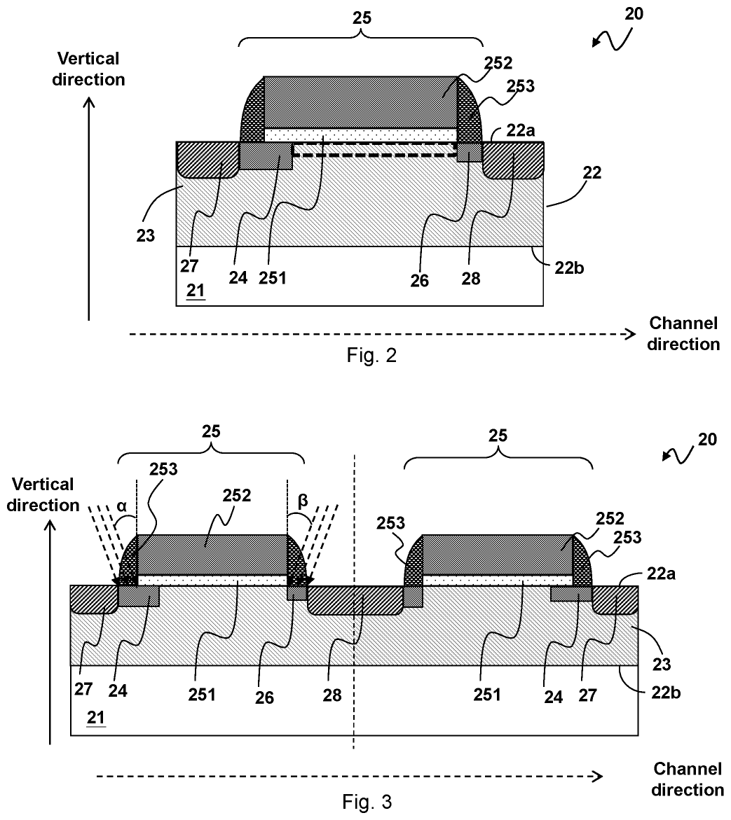

Please refer to FIG. 2 which shows a first embodiment of the present invention. FIG. 2 shows a schematic diagram of a cross-section view of a metal oxide semiconductor (MOS) device 20 capable of reducing ON-resistance. As shown in FIG. 2, the MOS device 20 includes a semiconductor layer 22, a well 23, a first lightly doped diffusion (LDD) region 24, a gate 25, a second LDD region 26, a drain 27 and a source 28.

The semiconductor layer 22 is formed on a substrate 21, and the semiconductor layer 22 has a top surface 22a and a bottom surface 22b that is opposite to the top surface 22a in the vertical direction (as indicated by the direction of the solid arrow in FIG. 2). The substrate 21 is, for example but not limited to, a P-type or N-type silicon substrate. The semiconductor layer 22, for example, is formed on the substrate 21 by an epitaxial growth process step, or, a part of the substrate 21 is used as the semiconductor layer 22. The semiconductor layer 22 can be formed by any method known to a person having ordinary skill in the art, so the details thereof are not redundantly explained here.

The well 23 having a first conductivity type is formed in the semiconductor layer 22, and is formed below and in contact with the top surface 22a. The gate 25 is formed on the top surface 22a of the semiconductor layer 22, wherein part of the well 23 is located below and in contact with the gate 25 in the vertical direction, to provide an inversion current channel (indicated by a dashed frame shown in the figure) in an ON operation of the MOS device 20.

Still referring to FIG. 2, the gate 25 includes: a dielectric layer 251, a conductive layer 252, and a spacer layer 253. The dielectric layer 251 is formed on and in contact with the top surface 22a, and is in contact with the well 23 in the vertical direction. The conductive layer 252 is formed on and in contact with the dielectric layer 251, and serves as an electrical contact of the gate 25. The spacer layer 253 is formed on two sidewalls of the conductive layer 252, and serves as an electrical insulation layer of the gate 25.

The drain 27 and the source 28 which have a second conductivity type are formed below and in contact with the top surface 22a in the vertical direction, wherein the drain 27 and the source 28 are located below and outside two sides of the gate 25 respectively in a channel direction, wherein the drain 27 and the source 28 are located in the well 23, and adjacent to the gate 25. An inversion current channel is formed between the drain 27 and the source 28, and the inversion current channel separates the source drain 27 and the source 28 at two sides of the gate 25.

The first LDD region 24 having the second conductivity type is formed below and in contact with the top surface 22a in the vertical direction. The first LDD region 24 is formed below and in contact with the dielectric layer 251 and the spacer layer 253, and the first LDD region 24 is located between and in contact with the drain 27 and the inversion current channel. The first LDD region 24 separates the drain 27 and the inversion current channel.

The second LDD region 26 having the second conductivity type is formed below and in contact with the top surface 22a in the vertical direction. The second LDD region 26 is formed below and in contact with the spacer layer 253, wherein the second LDD region 26 is in contact with the source 28 in the channel direction. In one preferable embodiment, the depth of the first LDD region 24 is deeper than the depth of the second LDD region 26 in the vertical direction.

The length of the first LDD region 24 is longer than the length of the second LDD region 26 in the channel direction. The impurity concentration of the second LDD region 26 is higher than the impurity concentration of the first LDD region 24.

Note that the term “inversion current channel” means thus. Taking this embodiment as an example, when the high voltage device 20 operates in ON operation due to the voltage applied to the gate 25, an inversion layer is formed below the gate 25, so that a conduction current flows through the region of the inversion layer, which is the inverse current channel known to a person having ordinary skill in the art.

In one preferable embodiment, as shown in FIG. 3 which is a schematic diagram showing the steps for forming the first LDD region 24 and the second LDD region 26, the first LDD region 24 is formed by a first self-alignment process, and the first self-alignment process includes for example but not limited to: using the conductive layer 252 and the dielectric layer 251 as a mask; and implanting second conductivity type impurities in the semiconductor layer 22 in the form of accelerated ions with a first angle α with reference to the vertical direction.

In one preferable embodiment, the second LDD region 26 is formed by a second self-alignment process, and the second self-alignment process includes for example but not limited to: using the conductive layer 252 and the spacer layer 253 as a mask; and implanting second conductivity type impurities in the semiconductor layer 22 through the spacer layer 253 in the form of accelerated ions with a second angle β with reference to the vertical direction, wherein the first angle α is larger than the second angle β. In another embodiment, the second self-alignment process may be performed without using the spacer layer 253 as the mask, that is, the second self-alignment process is performed by using the conductive layer 252 and the dielectric layer 251 as the mask instead, and implanting second conductivity type impurities in the semiconductor layer 22 in the form of accelerated ions with the second angle β with reference to the vertical direction to form the second LDD region 26. (In this case, the second angle β can be as small as 0.)

One technical feature of the present invention which is advantageous over the prior art is that, according to the present invention, taking the embodiment shown in FIG. 2 as an example, the first LDD region 24 of the MOS device 20 is formed right below part of the dielectric layer 251 and right below the complete bottom surface of one side of the spacer layer 253, and is in contact with the drain 27; besides, the second LDD region 26 of the MOS device 20 is formed below another side of the spacer layer 253, and is in contact with the spacer layer 253 and the source 28, wherein the length of the first LDD region 24 is longer than the length of the second LDD region 26; this arrangement increases the breakdown voltage of the MOS device 20.

Besides, in one preferable embodiment, the impurity concentration of the second LDD region 26 is higher than the impurity concentration of the first LDD region 24, to decrease the ON-resistance of the MOS device 20. This arrangement is for compensating the increase of ON-resistance due to that the second LDD region 26 does not extend to the channel region, which is different from the LDD region 16a in the prior art. In one preferable embodiment according to the present invention, the second LDD region 26 is in contact with the spacer layer 253 at the source side (i.e., the side which is closer to the source 28), but is not in contact with the dielectric layer 251 (different from the LDD region 16a of the MOS device 10), for increasing the breakdown voltage. Besides, in one embodiment, the second self-alignment process for forming the second LDD region 26 is different from a process for forming the LDD region 16a in the prior art in that, according to the present invention, the second self-alignment process for example uses the conductive layer 252 and the spacer layer 253 as the mask; but the process step for forming the LDD region 16a in the prior art uses only the conductive layer 152 as the mask. The second self-alignment process according to the present invention can form the second LDD region 26 shallower than the LDD region 16a in the prior art to increase the breakdown voltage.

Compared to the prior art MOS device, on one hand, the MOS device according to the present invention has a longer effective inversion current channel, and thus, the short channel effect such as the drain-induced barrier lowering (DIBL) effect, the hot carrier effect (HCE) and the threshold voltage roll-off effect can be mitigated; on the other hand, in the MOS device according to the present invention, the source side LDD (i.e. the LDD region near the source, which is the second LDD region 26 shown in the first embodiment) has a higher impurity concentration, which can decrease the ON-resistance and increase the response speed of the MOS device, to increase the performance of the MOS device.

Note that the above-mentioned “first conductivity type” and “second conductivity type” mean that impurities of corresponding conductivity types are doped in regions of the high voltage MOS device (for example but not limited to the aforementioned well region, body region, source and drain, etc.), so that the regions have the corresponding conductivity types. For example the first conductivity type is N-type and the second conductivity type is P-type, or the first conductivity type is P-type and the second conductivity type is N-type.

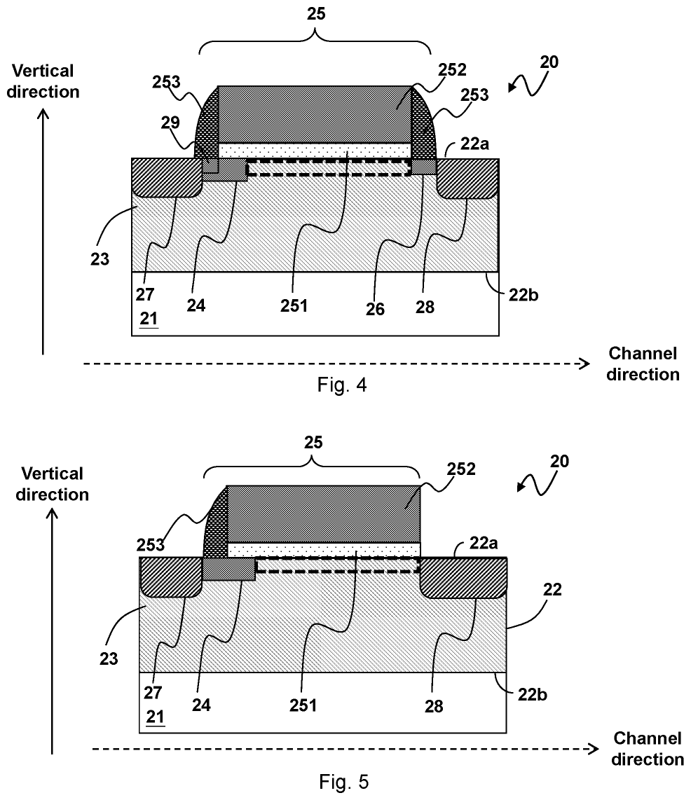

Please refer to FIG. 4 which shows a second embodiment of the present invention. Compared to the first embodiment shown in FIG. 2, this embodiment shows that the MOS device 20 capable of reducing ON-resistance further includes another second LDD region 29 (the second LDD region 26 is a first part of the second LDD region, and the second LDD region 29 is a second part of the second LDD region). The second LDD region 29 is located in the first LDD region 24, formed below and in contact with the spacer layer 253 at the drain side (i.e., the side of the space layer 253 which is closer to the drain 27).

Please refer to FIG. 5 which shows a third embodiment of the present invention. As shown in FIG. 5, the MOS device 20 includes a semiconductor layer 22, a well 23, a first LDD region 24, a gate 25, a drain 27 and a source 28. The semiconductor layer 22 is formed on the substrate 21, and the semiconductor layer 22 has the top surface 22a and the bottom surface 22b that is opposite to the top surface 22a in the vertical direction (as indicated by the direction of the solid arrow in FIG. 5). The substrate 21 is, for example but not limited to, a P-type or N-type silicon substrate. The semiconductor layer 22, for example, is formed on the substrate 21 by an epitaxial growth process step, or, a part of the substrate 21 is used as the semiconductor layer 22. The semiconductor layer 22 can be formed by any method known to a person having ordinary skill in the art, so the details thereof are not redundantly explained here.

The well 23 having the first conductivity type is formed in the semiconductor layer 22, and is formed below and in contact with the top surface 22a. The gate 25 is formed on the top surface 22a of the semiconductor layer 22, wherein part of the well 23 is located below and in contact with the gate 25 in the vertical direction, to provide an inversion current channel (indicated by a dashed frame shown in the figure) in an ON operation of the MOS device 20.

Still referring to FIG. 5, the gate 25 includes: a dielectric layer 251, a conductive layer 252, and a spacer layer 253. The dielectric layer 251 is formed on and in contact with the top surface 22a, and is in contact with the well 23 in the vertical direction. The conductive layer 252 is formed on and in contact with the dielectric layer 251, and serves as an electrical contact of the gate 25.

The spacer layer 253 is formed on one sidewall of the conductive layer 252, and serves as an electrical insulation layer of the gate 25. The drain 27 and the source 28 are formed below and in contact with the top surface 22a in the vertical direction, wherein the source 28 is adjacent to a side of the gate 25 where there is no spacer layer, and the drain 27 is adjacent to the other side of the gate 25 with the spacer layer 253. The first LDD region 24 having the second conductivity type is formed below and in contact with the top surface 22a in the vertical direction. The first LDD region 24 having the second conductivity type is formed below and in contact with the dielectric layer 251 and the spacer layer 253, and the first LDD region 24 is in contact with the drain 27.

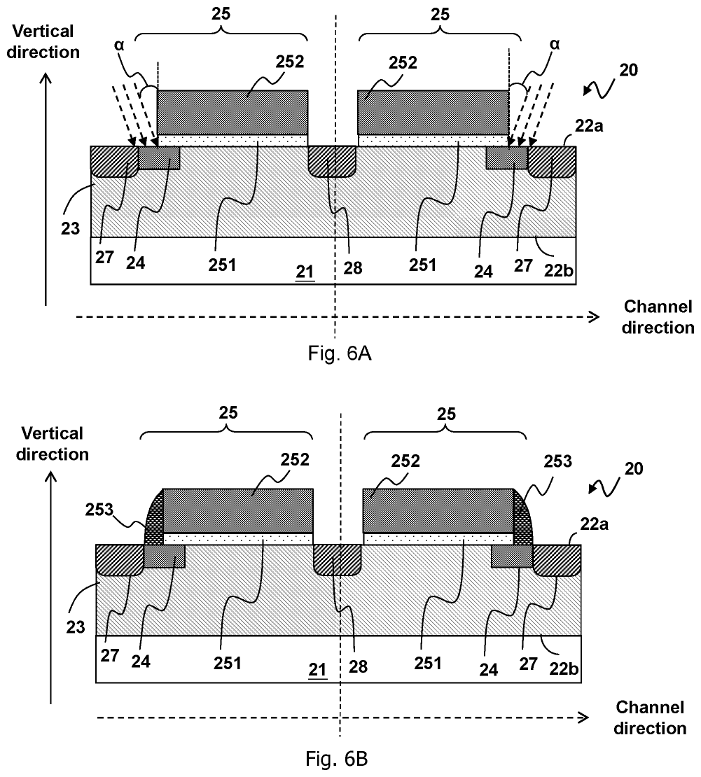

In one preferable embodiment, referring to FIGS. 6A and 6B wherein FIG. 6A is a schematic diagram showing the steps for forming the first LDD region 24, the first LDD region 24 is formed by a first self-alignment process which for example includes: using the conductive layer 252 and the dielectric layer 251 as a mask; and implanting second conductivity type impurities in the semiconductor layer 22 in the form of accelerated ions with a first angle α larger than 0 with reference to the vertical direction. FIG. 6B shows that the spacer layer 253 is formed at one side of the gate 25 after the first self-alignment process.

Note that, one technical feature of the present invention which is advantageous over the prior art is that, according to the present invention, taking the embodiment shown in FIG. 5 as an example, the source side of the gate 25 (i.e. the side of the gate 25 that is closer to the source 28) has no spacer layer, while the drain side of the gate 25 (i.e. the side of the gate 25 that is closer to the drain 27) has the spacer layer 253; besides, the first LDD region 24 having the second conductivity type is formed below and in contact with the dielectric layer 251 and the spacer layer 253, and the first LDD region 24 is in contact with the drain 27; this arrangement increases the breakdown voltage.

Furthermore, based on the third embodiment shown in FIG. 5, in the embodiment of FIGS. 6A and 6B, two MOS devices 20 shown are arranged in mirror arrangement to share the same source 28, to reduce the unit size of the MOS device 20.

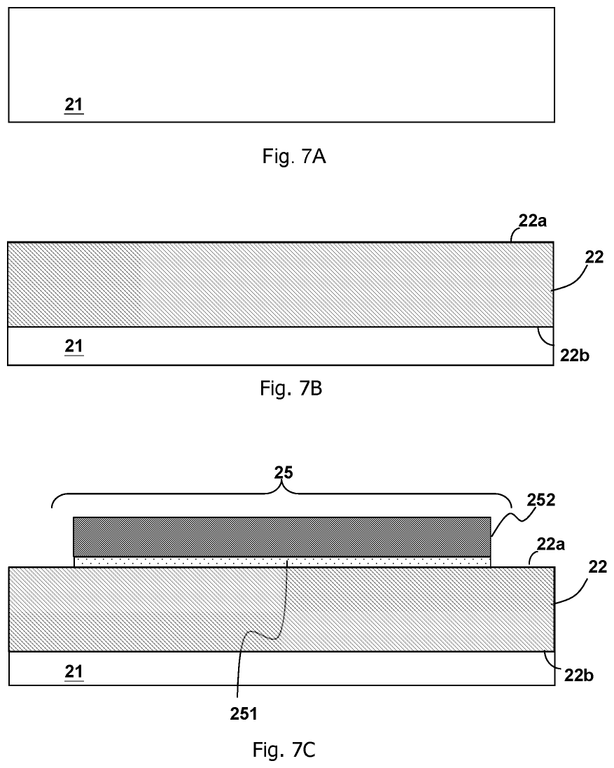

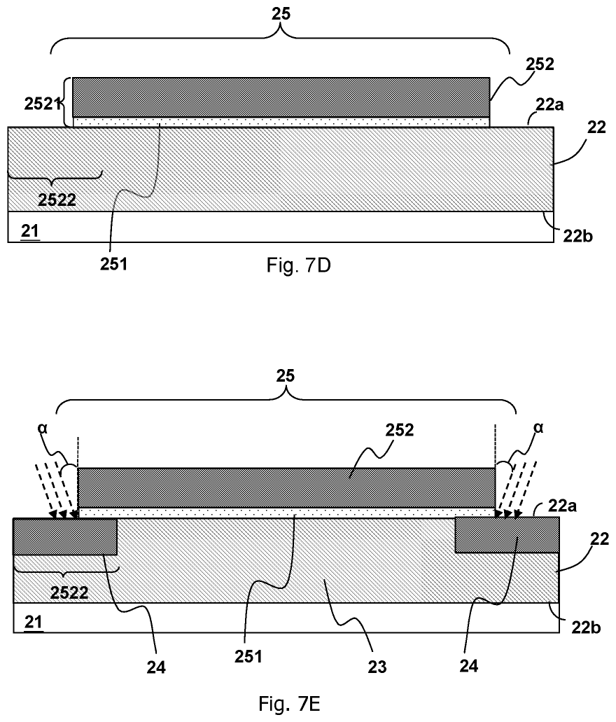

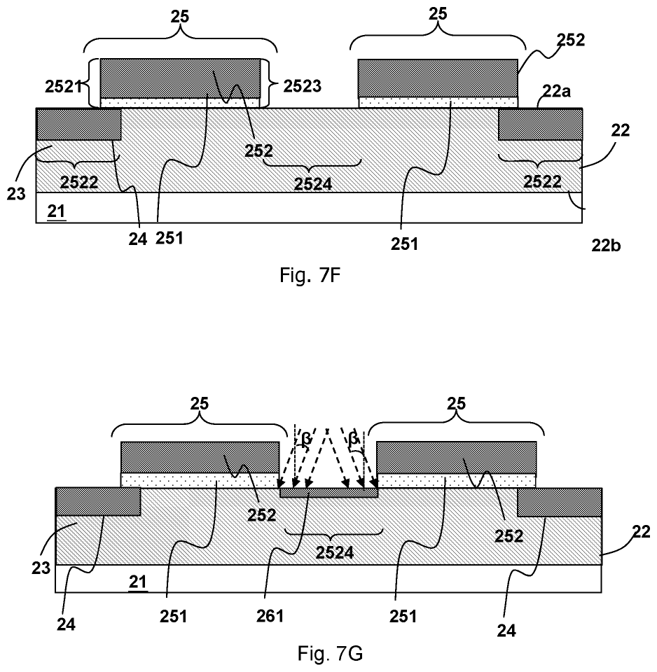

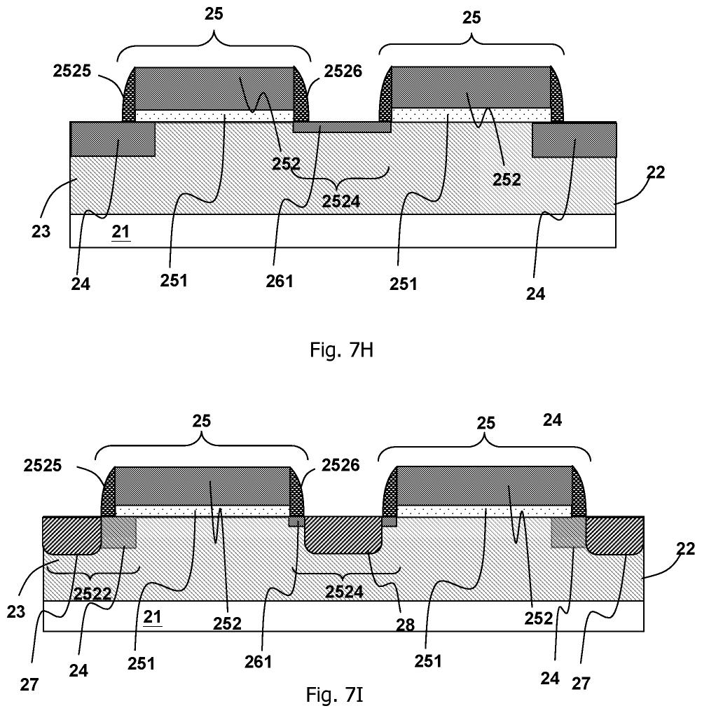

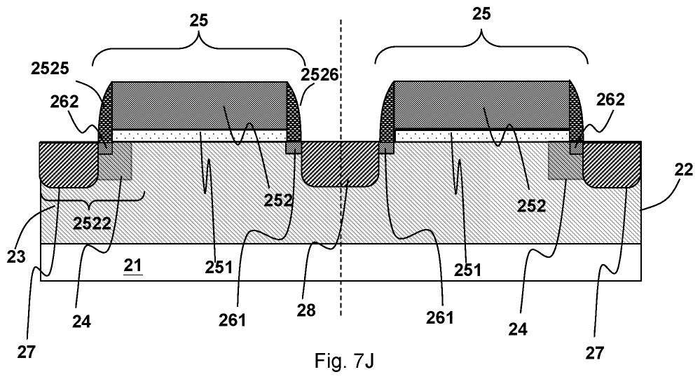

FIGS. 7A-7J are schematic diagrams showing a manufacturing method of a MOS device 20 according to the present invention. As shown in FIG. 7A, first, a substrate 21 is provided.

As shown in FIG. 7B, a semiconductor layer 22 is formed on the substrate 21, and the semiconductor layer 22 has the top surface 22a and the bottom surface 22b that is opposite to the top surface 22a in the vertical direction. The substrate 21 is, for example but not limited to, a P-type or N-type silicon substrate. The semiconductor layer 22, for example, is formed on the substrate 21 by an epitaxial growth process step, or, a part of the substrate 21 is used as the semiconductor layer 22. The semiconductor layer 22 can be formed by any method known to a person having ordinary skill in the art, so the details thereof are not redundantly explained here. Next, a well 23 having the first conductivity type is formed in the semiconductor layer 22, and the well 23 is located below and in contact with the top surface 22a. The well can be formed by, for example but not limited to, an ion implantation process step which implants first conductivity type impurities in the semiconductor layer 22 in the form of accelerated ions, to form the well 23.

As shown in FIG. 7C, a dielectric layer 251 and a conductive layer 252 on the dielectric layer 251, as part of the gate 25, are formed on the top surface 22a.

As shown in FIG. 7D, a first region 2522 is defined at a first side 2521 of the conductive layer 252. For example, the first region 2522 includes an area outside and below the first side 2521 in the semiconductor layer 22, plus a thermal diffusion area when impurities doped outside the first side 2521 in the semiconductor layer 22 thermally diffuse to reach inside the first side 2521.

As shown in FIG. 7E, a first LDD region 24 having the second conductivity type is formed in the first region 2522 by the first self-alignment process mentioned above, wherein the first LDD region 24 is below and in contact with part of the dielectric layer 251.

As shown in FIG. 7F, a second region 2524 is defined at a second side 2523 of the conductive layer 252. The first region 2522 and the second region 2524 are separated from each other by to well 23. For example, the second region 2524 includes an area outside and below the second side 2523 in the semiconductor layer 22, plus a thermal diffusion area when impurities doped outside the second side 2523 thermally diffuse to reach inside the semiconductor layer 22.

As shown in FIG. 7G, a first part 261 of the second LDD region 26 is formed in the second region 2524 by the second self-alignment process mentioned above. The second self-alignment process for forming the first part 261 of the second LDD region 26 includes for example but not limited to: using the conductive layer 252 and the dielectric layer 251 as a mask; and implanting second conductivity type impurities in the semiconductor layer 22 in the form of accelerated ions with the second angle β with reference to the vertical direction, wherein the second angle β is larger than 0.

As shown in FIG. 7H, a first spacer layer 2525 and a second spacer layer 2526 are formed on the first side 2521 and the second side 2523 of the conductive layer 252, respectively. The first LDD region 24 is below and in contact with the first spacer layer 2525 and part of the dielectric layer 251. The first part 261 of the second LDD region 26 is below and in contact with the second spacer layer 2526 but is not in contact with the dielectric layer 251.

As shown in FIG. 7I, the drain 27 and the source 28 are formed in the first region 2522 and the second region 2524, respectively. The first LDD region 24 is in contact with the drain 27 and the second LDD region 26 is in contact with the source 28.

As shown in FIG. 7J, a second part 262 of the second LDD region 26 having the second conductivity type is formed in the first region 2522. The second part 262 is located in the first LDD region 24 and below the first spacer layer 2525, and the second part 262 is in contact with the drain 27. In one embodiment, the second part 262 may be located also below part of the dielectric layer 251, besides below the first spacer layer 2525.

In one preferable embodiment, as shown in FIG. 7E, which is a schematic diagram showing the steps for forming the first LDD region 24, the first LDD region 24 is formed by the first self-alignment process. The first self-alignment process includes: using the conductive layer 252 and the dielectric layer 251 as a mask; and implanting second conductivity type impurities in the semiconductor layer 22 in the form of accelerated ions with a first angle α with reference to the vertical direction.

In one preferable embodiment, as shown in FIG. 7G, the second LDD region 26 is formed by a second self-alignment process, and the second self-alignment process includes: using the conductive layer 252 and the dielectric layer 251 as a mask; and implanting second conductivity type impurities in the semiconductor layer 22 in the form of accelerated ions with a second angle β with reference to the vertical direction, wherein the first angle α is larger than the second angle β.

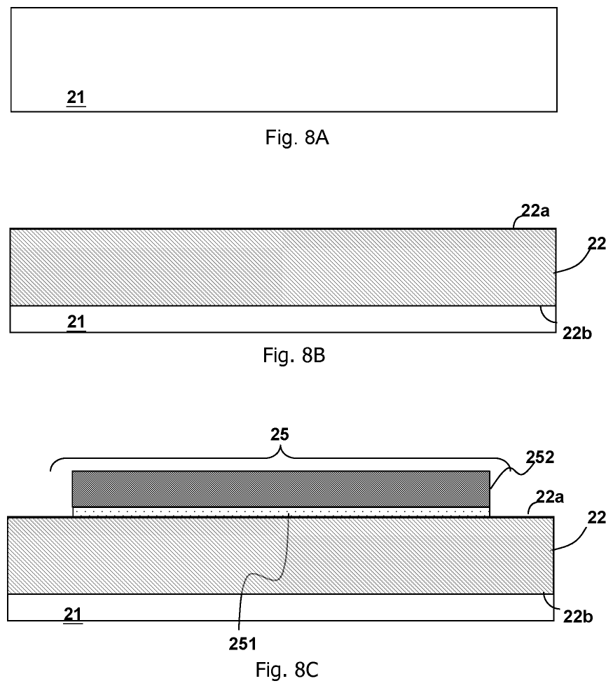

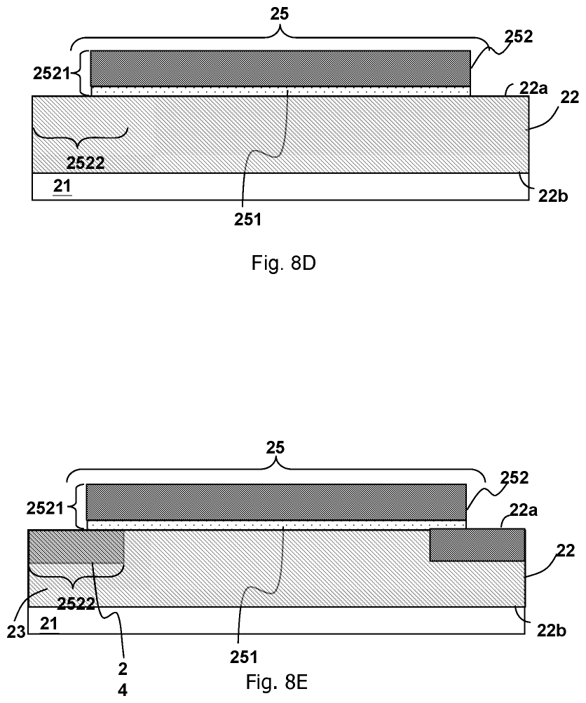

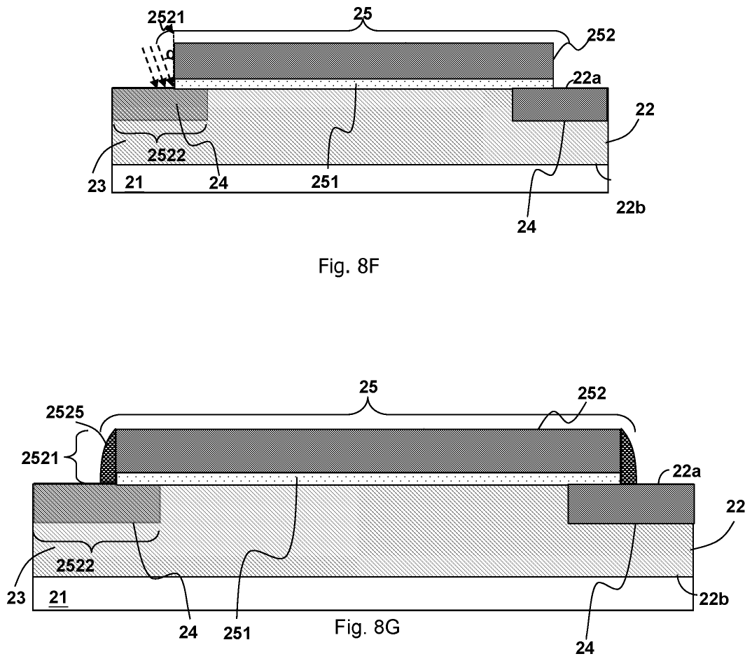

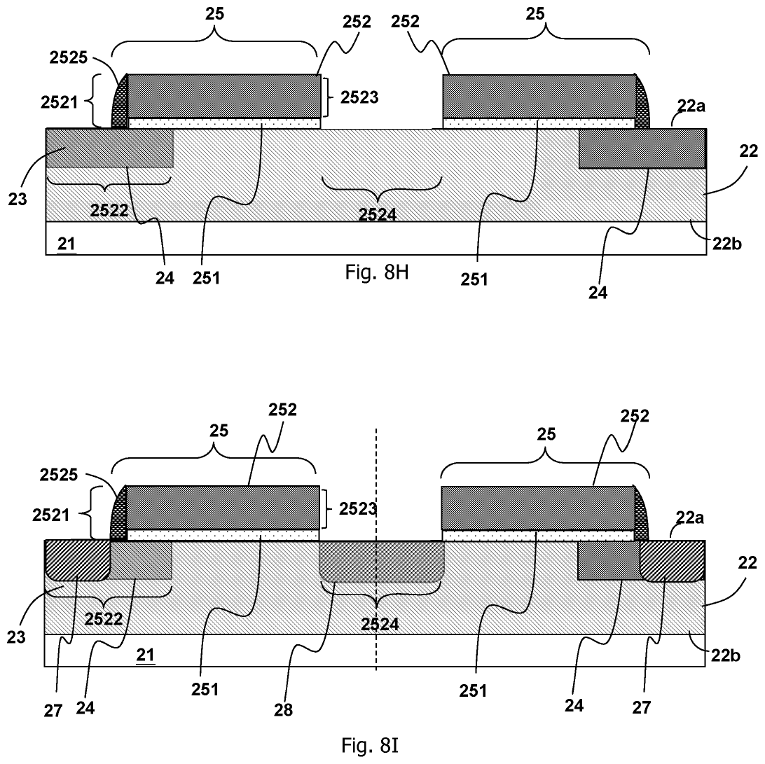

FIGS. 8A-8J are schematic diagrams showing another manufacturing method of the MOS device 20 according to the present invention. As shown in FIG. 8A, first, a substrate 21 is provided.

As shown in FIG. 8B, a semiconductor layer 22 is formed on the substrate 21, and the semiconductor layer 22 has the top surface 22a and the bottom surface 22b that is opposite to the top surface 22a in the vertical direction. The substrate 21 is, for example but not limited to, a P-type or N-type silicon substrate. The semiconductor layer 22, for example, is formed on the substrate 21 by an epitaxial growth process step, or, a part of the substrate 21 is used as the semiconductor layer 22. The semiconductor layer 22 can be formed by any method known to a person having ordinary skill in the art, so the details thereof are not redundantly explained here.

As shown in FIG. 8C, a dielectric layer 251 and a conductive layer 252 on the dielectric layer 251, as part of the gate 25, are formed on the top surface 22a.

As shown in FIG. 8D, a first region 2522 is defined at a first side 2521 of the conductive layer 252.

As shown in FIG. 8E, a well 23 having the first conductivity type is formed in the semiconductor layer 22, and the well 23 is located below the top surface 22a and in contact with the bottom surface 22b.

As shown in FIG. 8F, a first LDD region 24 having the second conductivity type is formed in the first region 2522 by the first self-alignment process, wherein the first LDD region 24 is below and in contact with part of the dielectric layer 251. In one preferable embodiment, as shown in FIG. 8F, which is a schematic diagram showing the steps for forming the first LDD region 24, the first self-alignment process includes: using the conductive layer 252 and the dielectric layer 251 as a mask; and implanting second conductivity type impurities in the semiconductor layer 22 in the form of accelerated ions with a first angle α with reference to the vertical direction, wherein the first angle α is larger than 0.

As shown in FIG. 8G, a first spacer layer 2525 is formed on the first side 2521 of the conductive layer 252, and the first LDD region 24 is below and in contact with the first spacer layer 2525 and part of the dielectric layer 251.

As shown in FIG. 8H, a second region 2524 is defined at a second side 2523 of the conductive layer 252.

As shown in FIG. 8I, the drain 27 and the source 28 are formed in the first region 2522 and the second region 2524, respectively. The drain 27 and the source 28 are formed below the top surface 22a, wherein the source 28 is adjacent to the second side 2523 of the gate 25 where there is no spacer layer (compared to FIG. 7I), and the drain 27 is adjacent to the first side 2521 of the gate 25 with the first spacer layer 2525.

Furthermore, as the embodiment of FIGS. 7A-7J also shows and as the embodiment of FIGS. 8A-8J also shows, the present invention provides a manufacturing method for manufacturing two MOS devices which are arranged in mirror arrangement concurrently by one manufacturing process. The two MOS devices 20 which are arranged in mirror arrangement share the same source 28 (the two MOS devices 20 are separated by a dashed line at the center of the source 28, referring to FIGS. 7J and 8I), so that the unit size of the MOS device 20 is reduced. The two MOS devices in mirror arrangement are shown in the embodiments of FIGS. 3, 6A and 6B, 7J, and 8I. The dashed line at the center of the source 28 separates the two MOS devices 20, wherein either one of the MOS devices 20 is a mirror image of the other MOS device 20 reflected from the dashed line at the center of the source 28, and the two MOS devices 20 have the same size.

The present invention is different from the prior art at least in that:

1. According to the present invention, in one embodiment, the length of the first LDD region is longer than the length of (the first part of) the second LDD region, and the impurity concentration of (the first part of) the second LDD region is higher than the impurity concentration of the first LDD region.

2. According to the present invention, in one embodiment, the source is adjacent to a side of the gate where there is no spacer layer, the drain is adjacent to the other side of the gate with the spacer layer; besides, the MOS device has a first LDD region which is formed below the dielectric layer and the spacer layer and is in contact with the drain.

As thus, the MOS device according to the present invention can mitigate the SCE including the DIBL, HCE and the threshold voltage roll-off effect, and increase the breakdown voltage. Besides, the present invention provides a MOS structure including two MOS devices which are arranged in mirror arrangement and share a same source, to reduce the unit size of the MOS device.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. The various embodiments described above are not limited to being used alone; two embodiments may be used in combination, or a part of one embodiment may be used in another embodiment. For example, other process steps or structures, such as a threshold voltage adjustment region, may be added. Therefore, in the same spirit of the present invention, those skilled in the art can think of various equivalent variations and various combinations, and there are many combinations thereof, and the description will not be repeated here. The scope of the present invention should include what are defined in the claims and the equivalents.

What is claimed is:

1. A metal oxide semiconductor (MOS) device, comprising:
a semiconductor layer which has a top surface and a bottom surface opposite to the top surface in a vertical direction;
a well having a first conductivity type, which is formed in the semiconductor layer, wherein the well is located below and in contact with the top surface;
a gate, which is formed on the top surface, wherein part of the well is located below and in contact with the gate in the vertical direction, the gate including:
a dielectric layer, which is formed on and in contact with the top surface, and is in contact with the well in the vertical direction;
a conductive layer, which is formed on and in contact with the dielectric layer, and serves as an electrical contact of the gate; and
a spacer layer, which is formed on two sidewalls of the conductive layer, and serves as an electrical insulation layer of the gate;
a source and a drain which have a second conductivity type and are formed below and in contact with the top surface in the vertical direction, wherein the source and the drain are located below and outside two sides of the gate respectively, and wherein the source and the drain are located in the well;
a first lightly doped diffusion (LDD) region having the second conductivity type, which is formed below the dielectric layer and the spacer layer, wherein the first LDD region is in contact with the drain; and
a first part of a second lightly doped diffusion (LDD) region having the second conductivity type, which is formed below and in contact with the spacer layer, wherein the first part of the second LDD region is in contact with the source;
wherein a length of the first LDD region is longer than a length of the first part of the second LDD region; and
wherein an impurity concentration of the first part of the second LDD region is higher than an impurity concentration of the first LDD region.

2. The MOS device of claim 1, wherein the first conductivity type is a P-type semiconductor conductivity type and the second conductivity type is an N-type semiconductor conductivity type; or the first conductivity type is an N-type semiconductor conductivity type and the second conductivity type is a P-type semiconductor conductivity type.

3. The MOS device of claim 1, wherein the first LDD region is formed by a first self-alignment process, and the first self-alignment process includes: using the conductive layer and the dielectric layer as a mask; and implanting second conductivity type impurities in the semiconductor layer in the form of accelerated ions with a first angle with reference to the vertical direction.

4. The MOS device of claim 3, wherein the first part of the second LDD region is formed by a second self-alignment process, and the second self-alignment process includes: using the conductive layer as a mask; and implanting second conductivity type impurities in the semiconductor layer through the spacer layer in the form of accelerated ions with a second angle with reference to the vertical direction, wherein the first angle is larger than the second angle.

5. The MOS device of claim 4, further comprising a second part of the second LDD region, wherein the second part of the second LDD region is located in the first LDD region, and the second part of the second LDD region is formed below and in contact with the spacer layer.

6. The MOS device of claim 1, wherein a depth of the first LDD region is deeper than a depth of the second LDD region.

7. A metal oxide semiconductor (MOS) device, comprising:
a semiconductor layer which has a top surface and a bottom surface opposite to the top surface in a vertical direction;
a well which has a first conductivity type and is formed in the semiconductor layer, wherein the well is located below and in contact with the top surface;
a gate, which is formed on the top surface, wherein part of the well is located below and in contact with the gate in the vertical direction, the gate including:
a dielectric layer, which is formed on and in contact with the top surface, and is in contact with the well in the vertical direction;
a conductive layer, which is formed on and in contact with the dielectric layer, and serves as an electrical contact of the gate; and
a spacer layer, which is formed on and in contact with a drain sidewall of the conductive layer but is not formed on and in contact with a source sidewall of the conductive layer, to serve as an electrical insulation layer of the gate, wherein the drain sidewall is a sidewall of the conductive layer that is adjacent to the drain, and the source sidewall is a sidewall of the conductive layer that is adjacent to the source;
a source and a drain which have a second conductivity type and are formed below and in contact with the top surface in the vertical direction; wherein the source is located below and outside the source sidewall of the conductive layer; wherein the drain is located below and outside the spacer layer of the gate; and
a first lightly doped diffusion (LDD) region having the second conductivity type, which is formed below the dielectric layer and the spacer layer, wherein the first LDD region is in contact with the drain.

8. The MOS device of claim 7, wherein the first conductivity type is a P-type semiconductor conductivity type and the second conductivity type is an N-type semiconductor conductivity type; or the first conductivity type is an N-type semiconductor conductivity type and the second conductivity type is a P-type semiconductor conductivity type.

9. The MOS device of claim 7, wherein the first LDD region is formed by a first self-alignment process, and the first self-alignment process includes: using the conductive layer and the dielectric layer as a mask; and implanting second conductivity type impurities in the semiconductor layer in the form of accelerated ions with a first angle with reference to the vertical direction, wherein the first angle is at least larger than 0 degree.

10. A manufacturing method of a metal oxide semiconductor (MOS) device, the manufacturing method comprising:
providing a semiconductor layer, which has a top surface and a bottom surface opposite to the top surface in a vertical direction;
forming a well having a first conductivity type in the semiconductor layer, wherein the well is located below and in contact with the top surface;
forming a dielectric layer of a gate on the top surface, and forming a conductive layer on the dielectric layer;
defining a first region below a drain sidewall of the conductive layer;
forming a first lightly doped diffusion (LDD) region in the first region by a first self-alignment process, wherein the first LDD region has a second conductivity type and is below and in contact with the dielectric layer;
defining a second region below a source sidewall of the conductive layer, wherein the first region and the second region are separated by the well;
forming a first part of a second LDD region in the second region by a second self-alignment process, wherein the second LDD region has the second conductivity type;
forming a first spacer layer and a second spacer layer outside and in contact with the drain sidewall and the source sidewall of the conductive layer respectively, wherein the first LDD region is below and in contact with the first spacer layer and part of the dielectric layer, and the first part of the second LDD region is below and in contact with the second spacer layer; and
forming a drain and a source having the second conductivity type in the first region and the second region respectively, wherein the first LDD region is in contact with the drain and the first part of the second LDD region is in contact with the source;
wherein the drain sidewall is a sidewall of the conductive layer that is adjacent to the drain, and the source sidewall is a sidewall of the conductive layer that is adjacent to the source;
wherein a length of the first LDD region is longer than a length of the first part of the second LDD region; and
wherein an impurity concentration of the first part of the second LDD region is higher than an impurity concentration of the first LDD region.

11. The manufacturing method of claim 10, wherein the first self-alignment process includes:
using the conductive layer and the dielectric layer as a mask; and
implanting second conductivity type impurities in the semiconductor layer in the form of accelerated ions with a first angle with reference to the vertical direction.

12. The manufacturing method of claim 11, wherein the second self-alignment process includes:
using the conductive layer as a mask; and
implanting second conductivity type impurities in the semiconductor layer through the second spacer layer in the form of accelerated ions with a second angle with reference to the vertical direction, wherein the first angle is larger than the second angle.

13. The manufacturing method of claim 10, wherein the first conductivity type is a P-type semiconductor conductivity type and the second conductivity type is an N-type semiconductor conductivity type; or the first conductivity type is an N-type semiconductor conductivity type and the second conductivity type is a P-type semiconductor conductivity type.

14. The manufacturing method of claim 10, further comprising: forming a second part of the second LDD region having the second conductivity type in the first LDD region by the second self-alignment process, wherein the second part of the second LDD region is right below the first spacer layer and in contact with the drain.

15. The manufacturing method of claim 10, wherein two MOS devices which are arranged in mirror arrangement and share one common source are formed by the manufacturing method.

16. A manufacturing method of a metal oxide semiconductor (MOS) device, the manufacturing method comprising:
providing a semiconductor layer, which has a top surface and a bottom surface opposite to the top surface in a vertical direction;
forming a well having a first conductivity type in the semiconductor layer, wherein the well is located below and in contact with the top surface;
forming a dielectric layer of a gate on the top surface, and forming a conductive layer on the dielectric layer;
defining a first region below a drain sidewall of the conductive layer;
forming a first lightly doped diffusion (LDD) region in the first region by a first self-alignment process, wherein the first LDD region has a second conductivity type and is below and in contact with the dielectric layer;
forming a spacer layer outside the drain sidewall of the conductive layer but not outside a source sidewall of the conductive layer, wherein the first LDD region is below and in contact with the spacer layer and part of the dielectric layer;
defining a second region below the source sidewall of the conductive layer; and
forming a drain and a source having the second conductivity type in the first region and the second region respectively, wherein the first LDD region is in contact with the drain;
wherein the drain sidewall is a sidewall of the conductive layer that is adjacent to the drain, and the source sidewall is a sidewall of the conductive layer that is adjacent to the source;
wherein the source is located below and outside the source sidewall of the conductive layer;
wherein the drain is located below and outside the spacer layer of the gate;
wherein the source sidewall is adjacent to the source.

17. The manufacturing method of claim 16, wherein two MOS devices which are arranged in mirror arrangement and share one common source are formed by the manufacturing method.
